(19) United States
(12) Patent Application Publication
(10) Pub. No.: US 2025/0110413 A1
(43) Pub. Date: Apr. 3, 2025

(54) METHOD FOR COMPENSATING ACTUATOR EFFECTS OF ACTUATORS

(71) Applicant: Carl Zeiss SMT GmbH, Oberkochen (DE)

(72) Inventors: Markus RAAB, Schillingsfürst (DE); Stefan BAUEREGGER, Dillingen a. d. Donau (DE); Axel WITT, Rheinstetten (DE); Peter ESSIG, Karlsruhe (DE); Volker TIETSCH, Heidenheim (DE); Dagmar PAARMANN, Oberkochen (DE); Philipp JOERG, Aalen (DE); Matthias MANGER, Aalen (DE); Thilo POLLAK, Neresheim (DE)

(21) Appl. No.: 18/978,285

(22) Filed: Dec. 12, 2024

Related U.S. Application Data
(63) Continuation of application No. PCT/EP2023/063340, filed on May 17, 2023.

(30) Foreign Application Priority Data
Jun. 15, 2022 (DE) 10 2022 206 038.5

(51) Int. Cl. G03F 7/00

(52) U.S. Cl. CPC G03F 7/70758; G03F 7/70266; G03F 7/7085

(57) ABSTRACT

A method for driving an actuator for a component of a projection exposure apparatus for semiconductor lithography comprises: characterizing the actuator; parameterizing an actuator model; implementing the actuator model in a control structure; and driving the in actuator using the actuator model.

### CROSS-REFERENCE TO RELATED APPLICATIONS

The present application is a continuation of, and claims benefit under 35 USC 120 to, international application No. PCT/EP2023/063340, filed May 17, 2023, which claims benefit under 35 USC 119 of German Application No. 10 2022 206 038.5, filed Jun. 15, 2022. The entire disclosure of each of these applications is incorporated by reference herein.

### FIELD

The disclosure relates to a method for compensating actuator effects of actuators in projection exposure apparatuses for semiconductor lithography.

### BACKGROUND

Adaptive optical elements are becoming ever more relevant as the demands on lithography systems, especially in the DUV or EUV range, increase. For example, such elements may be in the form of deformable mirrors which can be driven within extremely short periods of time by actuators, for example, in order to compensate for a wavefront aberration as a result of a deformation of an optically effective surface of the mirror. The optically effective surface is the surface of the mirror on which the light used to image structures of a mask onto a wafer is incident during the normal operation of the apparatus.

Electrostrictive actuators, or else piezoactuators, which are classed among the ferro electric solid-state actuators, are frequently used as actuators. However, such actuators frequently exhibit unwanted effects, for example hysteresis and creep effects. This behaviour of the actuators can be especially damaging if what is known as a feed-forward method is used for driving the actuator system. The aforementioned method is distinguished in that it is merely an actuating signal generated in a control unit that is output to the actuator for the purpose of setting a desired state, for example the deflection of an actuator. The response of the system, which is to say the path actually travelled by the actuator, initially remains unconsidered for this type of control. Thus, very stringent demands are usually placed upon the model forming the basis for the calculation and output of the control signal for a desired deflection of the actuator.

### SUMMARY

The present disclosure seeks to provide a method by which it is possible to attain improved accuracy for driving actuators in projection exposure apparatuses for semiconductor lithography.

The disclosure provides a method for driving an actuator for an optical component of a projection exposure apparatus for semiconductor lithography, the method comprising:
characterizing the actuator;
parameterizing an actuator model;
implementing the actuator model in a control structure; and
driving the actuator using the actuator model.

According to the disclosure, as a result of the properties of the respective actuator finding consideration by way of the application of the actuator model when driving the actuator, it is possible to minimize an influence of certain undesirable effects on the precision of the actuator control. For example, this can bring about an improvement in the imaging quality, for example in the overlay performance of a projection exposure apparatus.

A reference step is performed at certain times in an embodiment of the disclosure. In this context, a reference step should be understood to mean a method step in which a defined state of the considered system is established. In this case, the considered system may comprise, for example, the model itself and its parameters, but also the real world, for example an actuator.

Thus, for example, the reference step can make it possible to take into consideration the circumstance that even a model merely present in software is subject to changes over a long period of time. For example, parameters set at the start of the method according to the disclosure may change, purely on account of the nature of the computer hardware, over a period of several days, weeks or years. Accordingly, it may be desirable to reset these parameters intermittently.

Moreover, it can be desirable to also intermittently put the driven actuator into a defined deflection state. As already mentioned above, the starting point and the direction in which a control voltage is applied definitely plays a role in the real actuator deflection. On the basis thereof, the real deflection of the actuator may travel along one of the two branches of a hysteresis curve. If a defined state is now set by way of an appropriately defined setting of the actuator deflection and the suitable choice of the subsequent driving direction, it is possible to ensure being on the correct branch of the hysteresis curve.

The period of time between the exposure of two wafers represents a choice for the time of the reference step. The few milliseconds of time available here are sufficient to perform the desired referencing. In this context, the referencing itself need not always comprise a resetting of the model and the control of the actuator; naturally, it is also conceivable to carry out only one of the two measures.

For example, one or more of the following actuator parameters lend themselves to the characterization of the actuator for the purpose of preparing the method according to the disclosure: change in length, frequency response, hysteresis, drift.

For example, the actuator can be characterized within a test environment. In this case, it is also conceivable to use not the actuator itself but a comparable sample for the characterization.

In an alternative, the actuator can be characterized in a projection exposure apparatus. One or more wafers can be exposed in this case, for example within a test run. The exposed wafers are subsequently measured. Then, the actuator parameters can likewise be determined from the ascertained image aberrations if a suitable model for the relationship between image aberrations and actuator properties is used.

In a variant of the disclosure, at least one separate model for at least one of the actuator parameters, which is subsequently superposed on at least one further model, is generated during the parameterization of the actuator model.

In this context, models for the drift can include:
Padde approximation;

$$S = a * tanh {( b * U )}^{2} + c ;$$

$$P = tanh ( b * U + c * P + d * {P}^{3} ) ;$$

S=a*P²; and
polynomials;
where S represents the actuator deflection, P represents the surface charge density, U represents the voltage, and a, b, c, d are fit parameters.

The following models, inter alia, are suitable for describing the hysteresis:
Bouc Wen;
Prandtl-Ishlinskii;and
Preisach.

Models for modelling the dynamics include inter alia:
superposed Pt1 functions;
superposed log functions; and
fractional differential equations.

A model developed as described above can be subsequently implemented in a controller which can be used to drive the actuator system of a component of a projection exposure apparatus.

For example the following options may be chosen for control purposes:
inverse model;
model-based control;
observer-based control;
subtracting of the actuator model;
machine learning control; and
neural network control.

For example, the actuator can be an electrostrictive actuator and a piezoelectric actuator or a magnetostrictive actuator.

For example, the actuator may be configured to position and also/or else deform the component.

The component can be an optical element, such as a mirror, optionally a deformable mirror.

### BRIEF DESCRIPTION OF THE DRAWINGS

Exemplary embodiments and variants of the disclosure will be explained in more detail hereinafter with reference to the drawings, in which:

FIG. 1 schematically shows a meridional section of a projection exposure apparatus for EUV projection lithography;

FIG. 2 schematically shows a meridional section of a projection exposure apparatus for DUV projection lithography;

FIG. 3 shows a typical actuator hysteresis curve;

FIG. 4 shows a typical drift behaviour of an actuator;

FIG. 5 shows a drift in the direction of the target deflection of an exemplary actuator;

FIG. 6 shows the deflection of an actuator counter to a voltage applied thereto;

FIG. 7 shows a consideration of the differences between the values obtained from the model and measurement;

FIGS. 8A-8D show different variants for implementing the model;

FIG. 9 shows the effect of the method according to the disclosure; and

FIG. 10 shows a flowchart for the method according to the disclosure.

### DETAILED DESCRIPTION

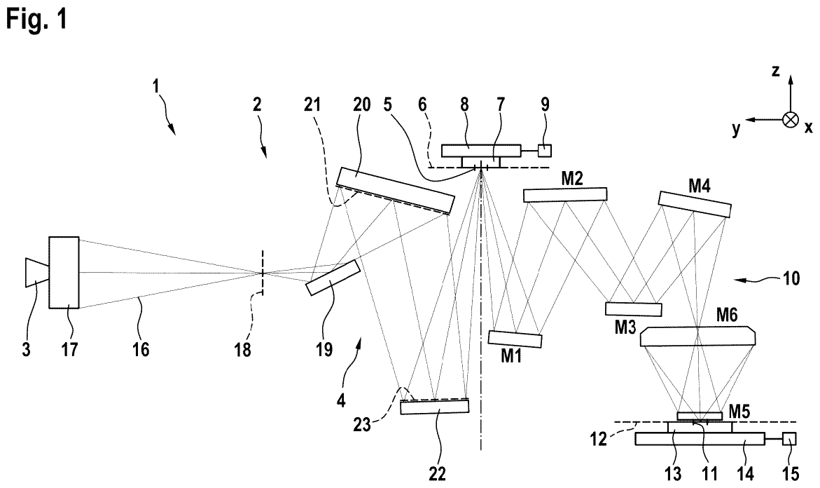

Certain parts of a microlithographic projection exposure apparatus 1 are described in exemplary fashion below initially with reference to FIG. 1. The description of the fundamental structure of the projection exposure apparatus 1 and the integral parts thereof is understood here to be non-limiting.

An embodiment of an illumination system 2 of the projection exposure apparatus 1 has, in addition to a radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9 in particular in a scanning direction.

A Cartesian xyz-coordinate system is shown in FIG. 1 for explanation purposes. The x-direction runs perpendicular to the plane of the drawing into the latter. The y-direction runs horizontally, and the z-direction runs vertically. The scanning direction runs in the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction. The displacement, firstly, of the reticle 7 by way of the reticle displacement drive 9 and, secondly, of the wafer 13 by way of the wafer displacement drive 15 may be implemented so as to be mutually synchronized.

The radiation source 3 is an EUV radiation source. The radiation source 3 emits EUV radiation 16, which is also referred to below as used radiation, illumination radiation or illumination light. For example, the used radiation has a wavelength in the range of between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), which is to say at angles of incidence of greater than 45° relative to the direction of the normal to the mirror surface, or with normal incidence (NI), which is to say at angles of incidence of less than 45°. The collector 17 can be structured and/or coated firstly for optimizing its reflectivity for the used radiation and secondly for suppressing extraneous light.

Downstream of the collector 17, the illumination radiation 16 propagates through an intermediate focus in an intermediate focal plane 18. The intermediate focal plane 18 can represent a separation between a radiation source module, having the radiation source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond a pure deflection effect. Alternatively or in addition, the deflection mirror 19 may be in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of the facets 21 by way of example.

The first facets 21 can be embodied in the form of macroscopic facets, for example in the form of rectangular facets or in the form of facets with an arcuate peripheral contour or a peripheral contour of part of a circle. The first facets 21 may be embodied as plane facets or alternatively as facets with convex or concave curvature.

As known for example from DE 10 2008 009 600 A1, the first facets 21 themselves can also be composed in each case of a multiplicity of individual mirrors, such as a multiplicity of micromirrors. For example, the first facet mirror 20 can be a microelectromechanical system (MEMS system). For details, reference is made to DE 10 2008 009 600 A1.

The illumination radiation 16 travels horizontally, which is to say in the y-direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or hexagonal boundary, or may alternatively be facets composed of micromirrors. In this regard, reference is likewise made to DE 10 2008 009 600 A1.

The second facets 23 may have plane reflection surfaces or alternatively convexly or concavely curved reflection surfaces.

The illumination optical unit 4 consequently forms a doubly faceted system. This fundamental principle is also referred to as a fly's eye condenser (fly's eye integrator).

It can be desirable to arrange the second facet mirror 22 not exactly in a plane that is optically conjugate to a pupil plane of the projection optical unit 10. For example, the pupil facet mirror 22 can be arranged so as to be tilted relative to a pupil plane of the projection optical unit 10, as is described, for example, in DE 10 2017 220 586 A1.

The individual first facets 21 are imaged into the object field 5 with the aid of the second facet mirror 22. The second facet mirror 22 is the last beam-shaping mirror or indeed the last mirror for the illumination radiation 16 in the beam path upstream of the object field 5.

In a further embodiment (not shown) of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror, or alternatively have two or more mirrors, which are arranged one behind the other in the beam path of the illumination optical unit 4. The transfer optical unit may for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

The deflection mirror 19 can also be dispensed with in a further embodiment of the illumination optical unit 4, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is, in general, only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection optical unit 10 is a doubly obscured optical unit. The projection optical unit 10 has an image-side numerical aperture which is greater than 0.5 and which can also be greater than 0.6 and, for example, can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16.

These coatings can be designed as multilayer coatings, for example with alternating layers of molybdenum and silicon.

The projection optical unit 10 has a large object-image offset in the y-direction between a y-coordinate of a centre of the object field 5 and a y-coordinate of the centre of the image field 11. This object-image offset in the y-direction can be of approximately the same magnitude as a z-distance between the object plane 6 and the image plane 12.

For example, the projection optical unit 10 can have an anamorphic embodiment. For example, it can have different imaging scales βx, βy in the x- and y-directions. The two imaging scales Bx, By of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, which is to say in a direction perpendicular to the scanning direction. The projection optical unit 10 leads to a reduction in size of 8:1 in the y-direction, which is to say in the scanning direction.

Other imaging scales are likewise possible. Imaging scales with the same sign and the same absolute value in the x-direction and y-direction are also possible, for example with absolute values of 0.125 or of 0.25.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x and y-directions are known from US 2018/0074303 A1.

In each case one of the pupil facets 23 is assigned to exactly one of the field facets 21 for forming in each case an illumination channel for illuminating the object field 5. For example, this can yield illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

By way of an assigned pupil facet 23, the field facets 21 are imaged in each case onto the reticle 7 in a manner overlaid on one another for the purposes of illuminating the object field 5. The illumination of the object field 5 is, for example, as homogeneous as possible. It can have a uniformity error of less than 2%. The field uniformity can be achieved by overlaying different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, in particular the subset of the pupil facets which guide light. This intensity distribution is also referred to as illumination setting.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described below.

The projection optical unit 10 may have a homocentric entrance pupil. The latter can be accessible. It can also be inaccessible.

The entrance pupil of the projection optical unit 10 cannot, as a rule, be exactly illuminated using the pupil facet mirror 22. The aperture rays often do not intersect at a single point when imaging the projection optical unit 10 which telecentrically images the centre of the pupil facet mirror 22 onto the wafer 13. However, it is possible to find an area in which the spacing of the aperture rays that is determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different poses of the tangential entrance pupil and 20 the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged so as to be tilted with respect to the object plane 6. The first facet mirror 20 is arranged so as to 25 be tilted with respect to an arrangement plane defined by the deflection mirror 19.

The first facet mirror 20 is arranged so as to be tilted with respect to an arrangement plane defined by the second facet mirror 22.

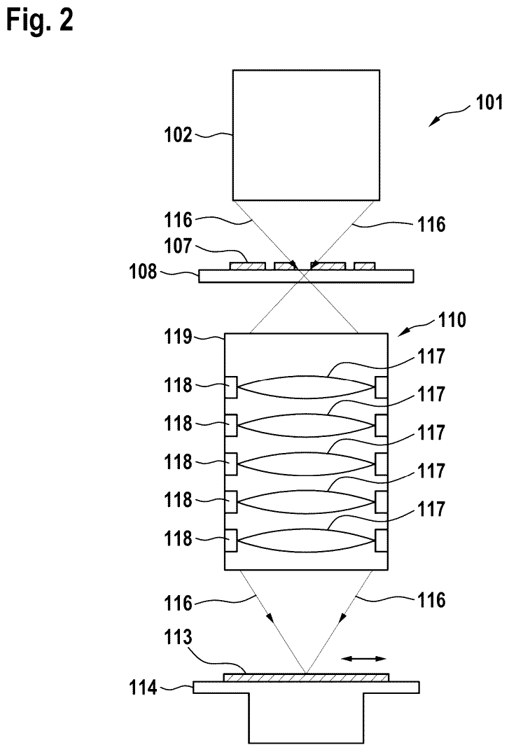

FIG. 2 schematically shows a meridional section of a further projection exposure apparatus 101 for DUV projection lithography, in which the disclosure can likewise be used.

The structure of the projection exposure apparatus 101 and the principle of the imaging are comparable with the construction and procedure described in FIG. 1. Identical component parts are denoted by a reference sign increased by 100 relative to FIG. 1, which is to say the reference signs in FIG. 2 begin with 101.

In contrast to an EUV projection exposure apparatus 1 as described in FIG. 1, refractive, diffractive and/or reflective optical elements 117, such as for example lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, such as of 193 nm. The projection exposure apparatus 101 in this case comprises an illumination system 102, a reticle holder 108 for receiving and exactly positioning a reticle 107 provided with a structure, by which the later structures on a wafer 113 are determined, a wafer holder 114 for holding, moving, and exactly positioning the wafer 113, and a projection lens 110, with a plurality of optical elements 117, which are held by way of mounts 118 in a lens housing 119 of the projection lens 110.

The illumination system 102 provides DUV radiation 116 for imaging the reticle 107 on the wafer 113. A laser, a plasma source or the like can be used as the source of this radiation 116. The radiation 116 is shaped in the illumination system 102 via optical elements such that the DUV radiation 116 has the desired properties with regard to diameter, polarization, shape of the wavefront and the 25 like when it is incident on the reticle 107.

Apart from the additional use of refractive optical elements 117, such as lens elements, prisms, terminating plates, the construction of the downstream projection optical unit 110 with the lens housing 119 does not differ in principle from the construction described in FIG. 1 and is therefore not described in further detail.

The apparatuses shown in FIGS. 1 and 2 each contain a multiplicity of components which can be positioned or else deformed via actuators. Thus, the properties of the actuators used to this end have an immediate effect on the performance of the apparatuses shown.

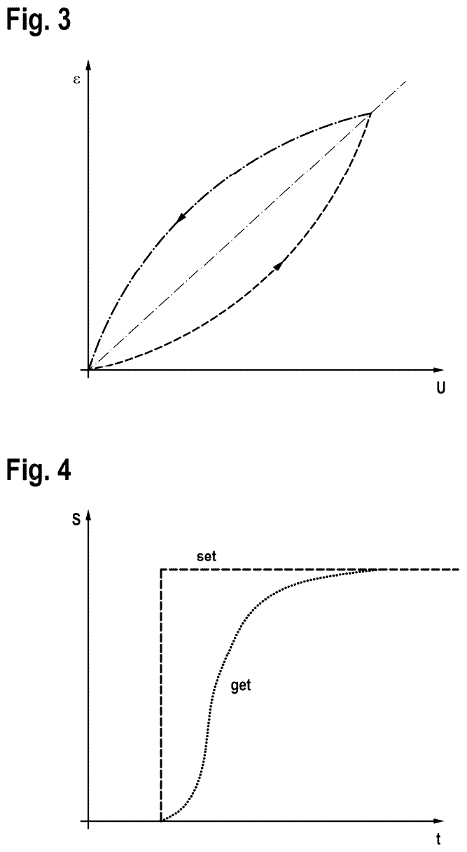

FIG. 3 schematically shows the behaviour of the mechanical strain of an actuator when a voltage is applied, until a maximum voltage is reached, and a subsequent retraction to a minimum voltage, 0 V in the example shown. This behaviour is known per se. The occurrence of a hysteresis is easily identifiable from the figure. In other words, the mechanical strain of the actuator for corresponding voltage values in the case of a fall in voltage does not correspond to the mechanical strain of the actuator in the case of an increase in voltage. In general, it is hard to explain the underlying effects from a physical point of view and these effects can only be modelled macroscopically.

Furthermore, as illustrated in FIG. 4, a typical actuator also has a certain drift behaviour in addition to the above-described effect of hysteresis. In other words, the desired deflection of an actuator is not set instantaneously, but with a certain time profile, even if a rectangular voltage signal is applied.

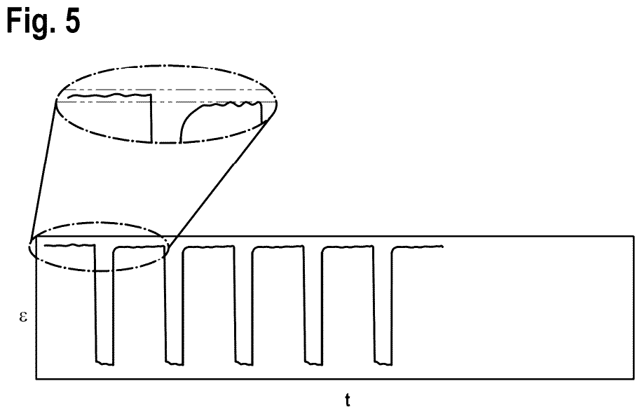

The aforementioned effects can be relevant if an actuator is to accomplish a significant deflection within a comparatively short period of time. This situation is elucidated on the basis of FIG. 5. The drift in the direction of the target deflection of an exemplary actuator during the first exposures of adjacent regions following a deflection of the actuator over a relatively large travel is easily identifiable in the figure. The assumption can be made that only an unsatisfactory imaging result can be obtained for these first regions.

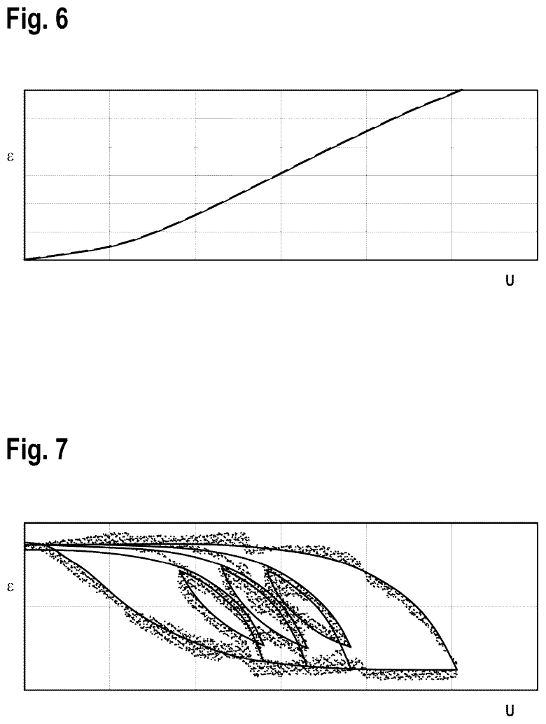

The mode of operation of the model should be explained in exemplary fashion on the basis of FIGS. 6 and 7 below.

In this case, the deflection of an actuator is plotted qualitatively against a voltage applied thereto in the illustration shown in FIG. 6. In this case, the real deflection is represented by a dashed curve while the curve generated on the basis of the model is represented by a dotted curve. The initially small deviation between the two curves is easily identifiable in the figure.

The quality and mode of operation of the model is only rendered identifiable if a consideration of the differences, as illustrated in FIG. 7, is carried out. The solid curve in FIG. 7 illustrates the result of subtracting from a curve generated on the basis of the complete model, which is to say under consideration of hysteresis and drift in particular, the curve which arises when a model that does not consider the aforementioned effects is used. This results in an illustration which clearly identifies the influence of the effects. As already mentioned, the solid curve is based only on a 10 model-based calculation.

The second graph illustrated in FIG. 7 arises from subtracting actually measured values for the deflection of the actuator in question from the ideal curve, which is to say the curve that would arise from the model if the effects are omitted. The high degree of correspondence between the two representations, which allows conclusions 15 to be drawn about the quality of the model used, is clearly identifiable in the figure.

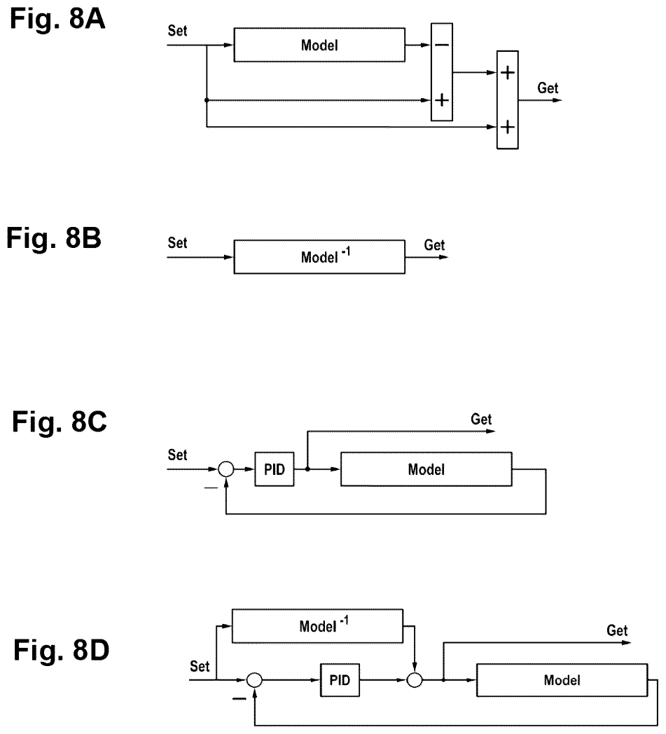

The illustrations shown in FIGS. 8A-8D show different variants for implementing the model.

Here, FIG. 8A initially visualizes a subtraction method. This method is substantially based on the fact that initially a certain target value of a deflection, for example 40 pm, is assumed. Subsequently, the model is used to determine the simulated deflection that would set-in under the assumption of the aforementioned target value. For example, if the model now supplies a value of 38 pm, then the difference of the two values, which is to say 2 pm, is applied to the target value which then forms the basis for the real control, in order to obtain the desired deflection.

FIG. 8B illustrates an inversion method. In this case, output and input are interchanged in the case of an invertible model and integrated into the controller.

FIG. 8C illustrates a model-based closed-loop control method. In this case, the planned actuating signal is initially used as starting value for the model, which subsequently supplies a certain travel. The travel simulated by the model is then supplied to a loop controller which performs a comparison between the desired model and the model obtained thereby, and subsequently adjusts the actuating signal, once again using the model, until the desired travel arises. As soon as this state is obtained, the actuating signal obtained in this manner is used to drive the actuator.

FIG. 8D shows a combination of the variants illustrated on the basis of FIGS. 8B and 8C. Naturally, combinations deviating therefrom are also possible.

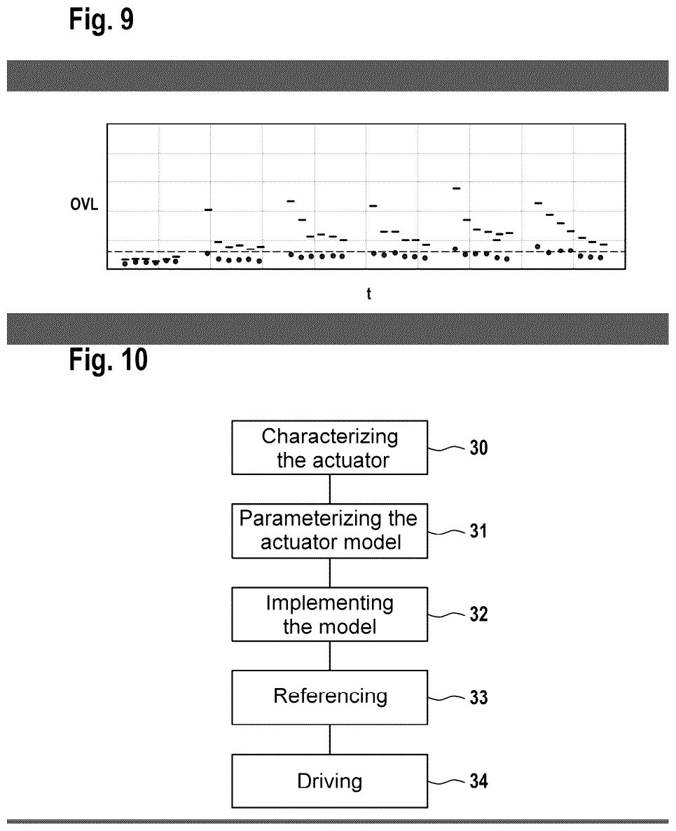

The effect of the method according to the disclosure is illustrated one more time on the basis of FIG. 9. Here, the overlay error of generated structures is plotted over time, in each case following the deflection of the actuator. Here, the individual exposure procedures are visualized using dots for the corrected case and dashes for the uncorrected case. For the uncorrected case, the significant error for the respective first exposure procedures of a group is clearly evident from the figure. As already explained above, this is due to the fact that, following a displacement over a significant travel, the actuator has not yet reached its sought end position at the beginning of the group. In contrast thereto, practically no deviation can be identified in the corrected case (illustrated using dots).

FIG. 10 shows a method procedure according to the disclosure schematically in a flowchart.

The following steps are illustrated:
characterizing 30 the actuator;
parameterizing 31 an actuator model;
implementing 32 the actuator model in a control structure;
driving 34 the actuator using the actuator model; and
the described referencing 33.

It is self-evident that the schematic illustration shown in FIG. 10 is purely exemplary. For example, the referencing 33 is an optional, albeit desirable step.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Method step of “characterizing the actuator”
31 Method step of “parameterizing the actuator model”
32 Method step of “implementing the model”
33 “Referencing” method step
34 “Driving” method step
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors

What is claimed is:

1. A method of driving an actuator for a component of a projection exposure apparatus for semiconductor lithography, the method comprising:
characterizing the actuator;
parameterizing an actuator model;
implementing the actuator model in a control structure; and
driving the actuator using the actuator model,
wherein characterizing the actuator is performed within the projection exposure apparatus.

2. The method of claim 1, further comprising performing a reference step at certain times.

3. The method of claim 2, wherein the reference step comprises a resetting of the model parameters.

4. The method of claim 2, wherein the reference step comprises homing in on a defined actuator position.

5. The method of claim 2, comprising performing the reference step between exposing a first wafer and a second wafer.

6. The method of claim 1, wherein characterizing the actuator comprises detecting at least one parameter selected from the group consisting of a change in length, a frequency response, hysteresis, and a drift.

7. The method of claim 1, further comprising generating at least one separate model for at least one of the actuator parameters, which is subsequently superposed on at least one further model, when parameterizing the actuator model.

8. The method of claim 1, wherein the actuator comprises a member selected from the group consisting of an electrostrictive actuator, a piezoelectric actuator, and a magnetostrictive actuator.

9. The method of claim 1, positioning the component using the actuator.

10. The method of claim 1, deforming the component using the actuator.

11. The method of claim 1, wherein the component comprises an optical element.

12. The method of claim 1, wherein the component comprises a mirror.

13. The method of claim 1, further comprising exposing a wafer in the projection exposure apparatus, wherein characterizing the actuator is based on image aberrations present during the wafer exposure.

14. The method of claim 13, performing a reference step at certain times.

15. The method of claim 1, further comprising exposing a wafer in the projection exposure apparatus, wherein characterizing a measurement of the exposed wafer.

16. The method of claim 15, further comprising performing a reference step at certain times.

17. The method of claim 1, further comprising performing a reference step at certain times wherein characterizing the actuator comprises detecting at least one parameter selected from the group consisting of a change in length, a frequency response, hysteresis, and a drift.

18. The method of claim 1, further comprising:
performing a reference step at certain times; and
generating at least one separate model for at least one of the actuator parameters, which is subsequently superposed on at least one further model, when parameterizing the actuator model.

19. The method of claim 1, further comprising performing a reference step at certain times, wherein the actuator comprises a member selected from the group consisting of an electrostrictive actuator, a piezoelectric actuator, and a magnetostrictive actuator.

20. The method of claim 1, further comprising:
performing a reference step at certain times positioning the component using the actuator; and
positioning the component and/or deforming the component using the actuator.
